(19) United States
(12) Patent Application Publication
(10) Pub. No.: US 2023/0078715 A1
(43) Pub. Date: Mar. 16, 2023

(54) DISPLAY ARRANGEMENT

(71) Applicant: Lumineq Oy, Espoo (FI)

(72) Inventor: Mika Sirkiä, Espoo (FI)

(21) Appl. No.: 17/904,681

(22) PCT Filed: Feb. 19, 2021
(86) PCT No.: PCT/FI2021/050125

§ 371 Date: Aug. 19, 2022

(30) Foreign Application Priority Data
Feb. 21, 2020 (FI) 20205175

(51) Int. Cl. G09G 3/30; H01L 27/15

(52) U.S. Cl. CPC G09G 3/30; H01L 27/156; G09G 2330/021; G09G 2320/0626; G09G 2330/028; G09G 2300/0426

(57) ABSTRACT

This specification relates to a display arrangement (1) comprising a thin film display element (100) and a display driver unit (200) configured to, while maintaining a second display terminal (222) associated with a second display electrode (122) in its high-impedance state, set a first display terminal (221) associated with a first display electrode (121) and a common display terminal (211) associated with a common display electrode (111), which at least partly laterally overlaps the first display electrode (121) and the second play electrode (122), to their first states and, after setting the first display terminal (221) and the common display terminal (211) to their first states, set the second display terminal (222) to its first state, while maintaining the first display terminal (221) and the common display terminal (211) in their high-impedance states, such that electrical current passes between the first display electrode (121) and the second display electrode (122).

### BACKGROUND

Electroluminescent displays comprise an emissive layer with electroluminescent phosphor material between two layers of conductors. In conventional thin film electroluminescent devices, an alternating or pulsed driving voltage is applied over such emissive layer between a pair of electrodes. Peak-to-peak amplitudes of such driving voltages may be relatively high, resulting in notable charging of the electrodes used to provide such driving voltages.

In conventional devices, each pair of electrodes is discharged after charging by driving both electrodes of the pair to the same electrical potential. Although such method has been proven suitable for use in a variety of circumstances, it may still be desirable to develop new solutions related to electroluminescent displays, for example, to reduce the power consumption and/or increase the brightness of electroluminescent displays.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter. A display arrangement is provided. The display arrangement comprises a thin film display element with a layer structure extending substantially along a base plane defining a lateral extension of the display element.

The display element comprises a first conductor layer, comprising a common display electrode, and a second conductor layer, comprising a first display electrode and a second display electrode, the common display electrode at least partly laterally overlapping each of the first display electrode and the second display electrode.

The display arrangement further comprises a display driver unit with a primary circuit node configured to be maintained at a first potential, a first display terminal associated with the first display electrode, a second display terminal associated with the second display electrode, and a common display terminal associated with the common display electrode.

Each of the first display terminal and the second display terminal has a first state, wherein said display terminal electrically couples its associated display electrode to the primary circuit node via a primary current path of said display terminal, and a high-impedance state, wherein said primary current path is disconnected. The common display terminal has a first state, wherein the common display electrode is maintained at a second potential and a high-impedance state.

The display driver unit has a rectifying first primary auxiliary current path between the first display electrode and the primary circuit node, and the display driver unit is configured to, while maintaining the second display terminal in its high-impedance state, set the first display terminal and the common display terminal to their first states and, after setting the first display terminal and the common display terminal to their first states, set the second display terminal to its first state, while maintaining the first display terminal and the common display terminal in their high-impedance states, such that electrical current passes between the first display electrode and the second display electrode along a forward direction of the first primary auxiliary current path and via the second display terminal.

### BRIEF DESCRIPTION OF THE DRAWINGS

The present disclosure will be better understood from the following detailed description read in light of the accompanying drawings, wherein:

FIGS. 1, 2, 3, 4, 5, 6, 7, and 8 illustrate schematic views of a display arrangement, and

FIG. 9 depicts a schematic view of a first display terminal.

Unless specifically stated to the contrary, any drawing of the aforementioned drawings may be not drawn to scale such that any element in said drawing may be drawn with inaccurate proportions with respect to other elements in said drawing in order to emphasize certain structural aspects of the embodiment of said drawing.

Moreover, corresponding elements in the embodiments of any two drawings of the aforementioned drawings may be disproportionate to each other in said two drawings in order to emphasize certain structural aspects of the embodiments of said two drawings.

### DETAILED DESCRIPTION

Concerning display arrangements discussed in this detailed description, the following shall be noted.

Throughout this specification, “potential”, “current”, “impedance” and “charge” may refer to electrical potential, electrical current, electrical impedance, and electrical charge, respectively.

In this disclosure, the terms “primary” and “secondary” may refer to elements related to primary circuit nodes and to secondary circuit nodes, respectively. Further, an ordinal number preceding such term may denote a display terminal related to an element. For example, a “first primary” element may refer to an element related both to a first display terminal and a primary circuit node.

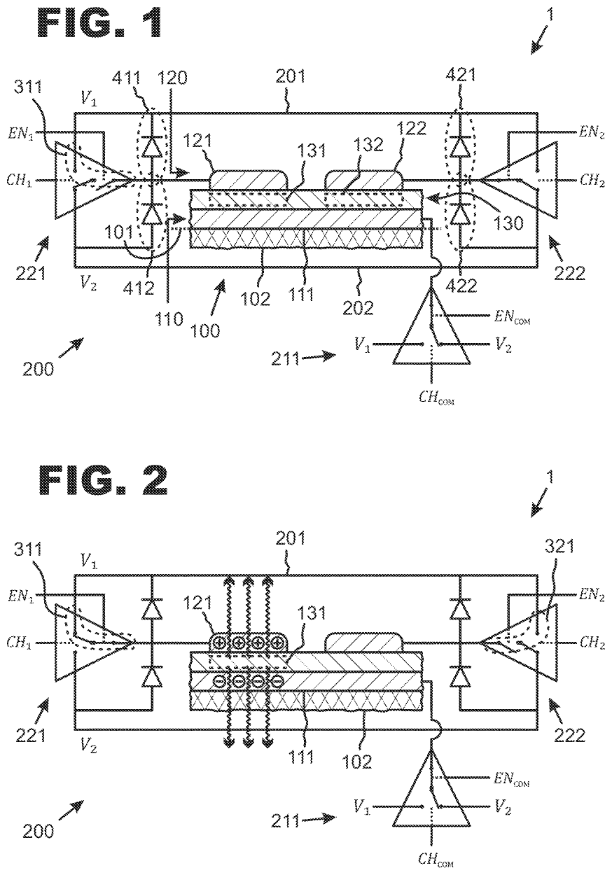

FIGS. 1 to 8 depict a display arrangement 1 according to an embodiment.

Herein, a “display arrangement” may refer to an arrangement which may form, as such, a complete, operable display. Alternatively, a display arrangement may be used as a part of a complete display comprising also other elements, units, and/or structures. A display arrangement may generally comprise at least one display element.

Throughout this specification, a “display element” may refer to an element comprising at least one emissive area for emitting light therefrom in order to present visual information.

With reference to FIG. 1, the display arrangement 1 of the embodiment of FIGS. 1 to 8 comprises a thin film display element 100.

Herein, a “thin film” display element may refer to a display element having a total thickness less than or equal to 50 μm, or less than or equal to 20 μm, or less than or equal to 10 μm. Individual layers may have thicknesses, for example, in a range from a few nanometers to some hundreds of nanometers or some micrometers.

The display element 100 of the embodiment of FIGS. 1 to 8 has a layer structure extending substantially along a fictitious base plane 101. The base plane 101 defines a lateral extension of the display element 100.

Herein, a “layer” may refer to a generally sheet-formed element arranged on a surface or a body. Additionally or alternatively, a layer may refer to one of a series of superimposed, overlaid, or stacked generally sheet-formed elements. A layer may generally comprise a plurality of sublayers of different materials or material compositions. A layer may be path-connected. Some layers may be locally path-connected and disconnected.

In this disclosure, a base plane “defining a lateral extension” of an element with a layer structure may refer to said element comprising a layer and having lateral directions along said base plane, in which lateral directions said element may have dimensions substantially larger than in a thickness direction perpendicular to said lateral directions.

In the embodiment of FIGS. 1 to 8, the display element 100 comprises a first conductor layer 110 and a second conductor layer 120. In other embodiments, a display element may generally comprise such first conductor layer and such second conductor layer.

Throughout this specification, a “conductor” may refer to an electrical conductor material and/or the electrical conductivity thereof. Consequently, a “conductor layer” may refer to a layer comprising a conductor material. Additionally or alternatively, a conductor layer may be electrically non-insulating, e.g., electrically conductive.

A conductor layer may comprise, for example, indium tin oxide (ITO), aluminum-doped zinc oxide (AZO, ZnO:Al), any other appropriate transparent conductive oxide (TCO), and/or any other transparent conductor material. Additionally or alternatively, a conductor layer may comprise metal, for example, a thin metal mesh. Generally, at least one of a first conductor layer and a second conductor layer of a display element may comprise a transparent material and/or structure.

The second conductor layer 120 of the embodiment of FIGS. 1 to 8 is arranged at a distance from the first conductor layer 110. In other embodiments, a second conductor layer may generally be arranged at a distance from a first conductor layer.

In the embodiment of FIGS. 1 to 8, the first conductor layer 110 comprises a common display electrode 111.

Throughout this specification, a “display electrode” may refer to an electrode functionally and/or electrically connectable and/or connected to a display driver unit. Additionally or alternatively, a display electrode may at least partly, i.e., partly or entirely, laterally overlap another display electrode. A display electrode may generally laterally overlap any suitable number, e.g., one, two, three, etc., of other display electrodes. Additionally or alternatively, a display electrode may be suitable for coupling electrical voltage over an emissive layer.

In this specification, an “emissive layer” may refer to layer comprising material capable of emitting light when electrical voltage is coupled over said emissive layer.

Herein, “light” may refer to electromagnetic radiation of any wavelength(s) within a range of relevant wavelengths. The range of relevant wavelengths may overlap or coincide with ultraviolet (wavelength from about 10 nanometers (nm) to about 400 nm), and/or visible (wavelength from about 400 nm to about 700 nm), and/or infrared (wavelength from about 700 nm to about 1 millimeter (mm)) parts of the electromagnetic spectrum.

Further, a “common display electrode” may refer to a display electrode laterally overlapping a plurality of (i.e., at least two, at least three, at least four, etc.) other display electrodes.

In the embodiment of FIGS. 1 to 8, the display arrangement 1 comprises an emissive layer 130 between the first conductor layer 110 and the second conductor layer 120. The emissive layer 130 is configured to emit light in consequence of voltage with a magnitude exceeding an activation voltage threshold (V_{TH}) coupled over the emissive layer 130. In other embodiments, a display arrangement may generally comprise such emissive layer.

The first conductor layer 110 of embodiment of FIGS. 1 to 8 is arranged onto a substrate 102. In other embodiments a first conductor layer may or may not be arranged onto a substrate.

In this specification, a “substrate” may refer to a solid body providing a surface, which may be flat or curved, such that material may be arranged, deposited, etched, and/or inscribed on the surface. A substrate may be formed, for example, of glass, e.g., sodalime, aluminosilicate, and/or any other appropriate glass or plastic. Suitable plastic materials include, for example, polyethylene (PE), polycarbonate (PC), and mixtures thereof, without being limited to these examples.

A substrate may mechanically protect a thin film display element and/or serve as an electrically insulating layer between said thin film display element and surroundings thereof. Further, there may also be another protective and/or insulating layer on an opposite side of said thin film display element. Such another layer may be formed by an external layer or element to which a display element is attached.

In the embodiment of FIGS. 1 to 8, the second conductor layer 120 comprises a first display electrode 121 and a second display electrode 122.

The first display electrode 121 of the embodiment of FIGS. 1 to 8 is arranged at a distance from the second display electrode 122. In other embodiments, a first display electrode may generally be arranged at a distance from a second display electrode.

The common display electrode 111 of the embodiment of FIGS. 1 to 8 entirely laterally overlaps each of the first display electrode 121 and the second display electrode 122. In other embodiments, a common display electrode may at least partly (i.e., partly or entirely) laterally overlap each of a first display electrode and a second display electrode.

Although in FIGS. 1 to 8, a single common display electrode, laterally overlapping two display electrodes, is depicted, a display element may generally comprise any suitable number, for example, one or more, two or more, three or more, etc., common display electrodes, each common display electrode laterally overlapping any suitable number, for example, two or more, three or more, four or more, etc., display electrodes.

The common display electrode 111 and the first display electrode 121 of the embodiment of FIGS. 1 to 8 define a first emissive part 131 of the emissive layer 130, where said conductor patterns overlap laterally. Correspondingly, the common display electrode 111 and the second display electrode 122 of the embodiment of FIGS. 1 to 8 define a second emissive part 132 of the emissive layer 130, where said conductor patterns overlap laterally. Generally, a common display electrode may be involved in defining a plurality of (i.e., at least two, at least three, at least four, etc.) emissive parts of an emissive layer.

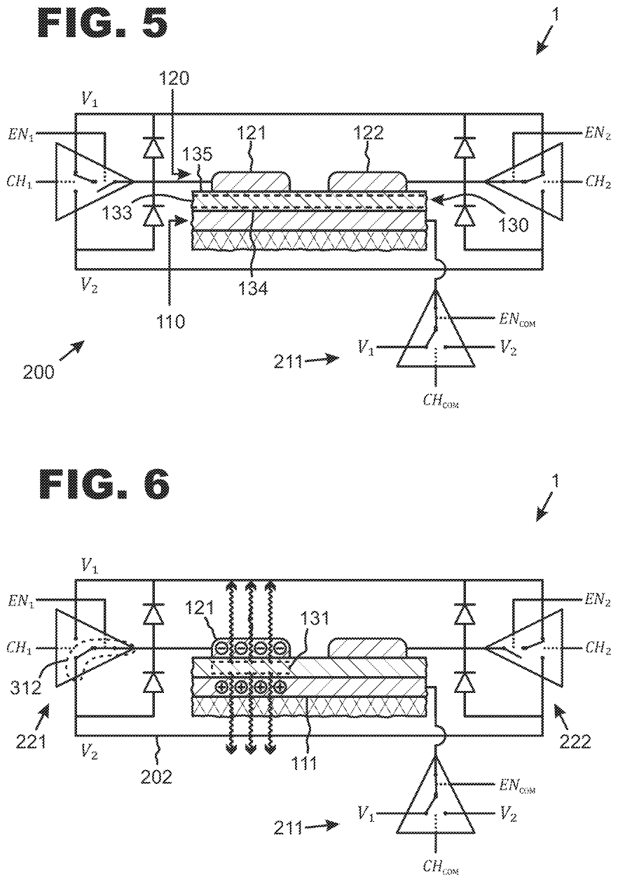

The display element 100 of the embodiment of FIGS. 1 to 8 may be implemented specifically as an inorganic thin film electroluminescent (TFEL) display element. Consequently, as depicted in FIG. 5 using dashed lines, the emissive layer 130 may comprise an inorganic phosphor layer 133, a first insulating layer 134 arranged between the phosphor layer 133 and the first conductor layer 110, and a second insulating layer 135 arranged between said phosphor layer 133 and the second conductor layer 120. In other embodiments, a thin film display element may or may not be implemented as an inorganic TFEL display element. A thin film display element may generally be implemented as any suitable type of display element.

Herein, an “inorganic thin film electroluminescent” type of display element may refer to a thin film display element comprising an emissive layer comprising an inorganic phosphor layer. In inorganic TFEL display elements, an emissive layer may further comprise a first insulating layer arranged between an inorganic phosphor layer and a first conductor layer, and a second insulating layer arranged between said phosphor layer and a second conductor layer. In inorganic TFEL displays, an alternating or pulsed driving voltage may be applied over such emissive layer. An inorganic TFEL display driven with pulsed or alternating voltages may be referred to as an inorganic “AC TFEL display”. Peak-to-peak amplitudes of such driving voltages may be, for example, few hundreds of volts, generated by a specific display driver unit and fed to display electrodes via conductors from display terminals of said display driver unit.

It is apparent to a person skilled in the art that a common display electrode may or may not be arranged as an elongated row or column electrode of a matrix-type display element, and one or more of a first display electrode and a second display electrode may or may not be arranged as an elongated column or row electrode, respectively, of said matrix-type display element.

Herein, a “matrix-type display element” may refer to a display element comprising a set of row electrodes and a set of column electrodes directed at an angle in relation to and laterally overlapping one another. Generally, such sets of electrodes may or may not be directed perpendicularly to one another. A TFEL display element organized as a matrix-type display element may be implemented as a passive matrix display element.

In the embodiment of FIGS. 1 to 8, the display arrangement 1 comprises a display driver unit 200.

Herein, a “display driver unit” may refer to a display-powering means suitable for and/or configured to supply electrical power to a display element of a display arrangement to bring about emission of light.

A display driver unit may or may not form a part of a multifunctional control system. In some embodiments, a display driver unit may be implemented as a separate unit, whereas in others a display driver unit may be implemented as a sub-unit of a control system further comprising other suitable sub-units.

A display driver unit being “configured to” perform a process may refer to capability of and suitability of said display driver unit for such process. This may be achieved in various ways. For example, a display driver unit may comprise at least one processor and at least one memory coupled to the at least one processor, the memory storing program code instructions which, when executed on said at least one processor, cause the processor to perform the process(es) at issue.

Additionally or alternatively, any functionally described features of a display driver unit may be performed, at least in part, by one or more hardware logic components. For example, and without limitation, illustrative types of suitable hardware logic components include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. A display driver unit may generally be operated in accordance with any appropriate principles and by means of any appropriate circuitry and signals known in the art for powering display elements of display arrangements.

In the embodiment of FIGS. 1 to 8, the display driver unit 200 comprises a primary circuit node 201, which is configured to be maintained at a first potential (V₁).

In the embodiment of FIGS. 1 to 8, the display driver unit 200 comprises a secondary circuit node 202, which is configured to be maintained at a second potential (V₂). In other embodiments, a display driver unit may or may not comprise such secondary circuit node.

In the embodiment of FIGS. 1 to 8, a magnitude of a potential difference |V₁−V₂| between the first potential V₁ and the second potential V₂ exceeds the activation voltage threshold V_{TH}. As such, the emissive layer 130 emits light in consequence of a voltage V₁−V₂ coupled over the emissive layer 130.

Owing to its physical nature, the emissive layer 130 may emit light in a pulsed manner. When light pulses are repeatedly brought about by a plurality of voltage pulses in rapid succession, such light pulses may be perceived as a constant source of light, owing to the persistence of vision, also referred to as flicker fusion.

In the embodiment of FIGS. 1 to 8, the first potential V₁ is higher than the second potential V₂. In other embodiments, a first potential V₁ may generally be higher or lower than a second potential V₂.

In the embodiment of FIGS. 1 to 8, the display driver unit 200 comprises a first display terminal 221 associated with the first display electrode 121, a second display terminal 222 associated with the second display electrode 122, and a common display terminal 211 associated with the common display electrode 111.

Herein, “terminal” may refer to an interface of a device whereto external elements, such as electrodes and/or electrical circuits, may be connected. The term “terminal” may also refer to any electronic components configured to modify electrical signals transmitted and/or received via said terminal.

Further, a “display terminal” may refer to a terminal of a display driver unit suitable for providing power to a display electrode in a display arrangement.

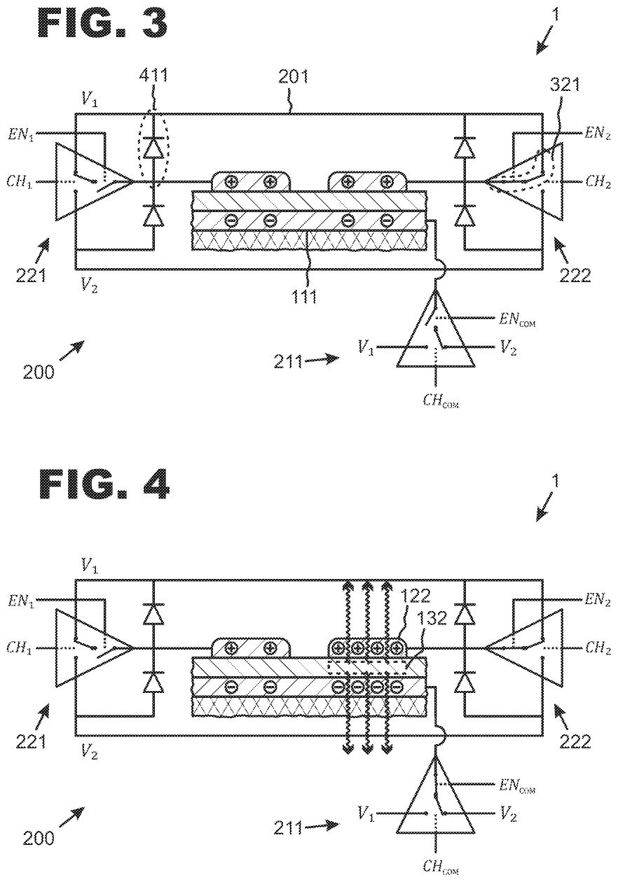

Each of the first display terminal 221 and the second display terminal 222 of the embodiment of FIGS. 1 to 8 has a first state. In its first state, the first display terminal 221 couples the first display electrode 121 to the primary circuit node 201 via its first primary current path 311, as illustrated in FIG. 2. Correspondingly, in its first state, the second display terminal 222 couples the second display electrode 122 to the primary circuit node 201 via its second primary current path 321, as illustrated in FIG. 3.

Throughout this disclosure, a “current path” may refer to an electrical connection between two elements, enabling a continuous flow of direct (i.e., unidirectional) electrical current between said elements.

Each of the first display terminal 221 and the second display terminal 222 of the embodiment of FIGS. 1 to 8 also has a high-impedance state. In the high-impedance state of the first display terminal 221, the first primary current path 311 is disconnected, as illustrated in FIG. 1. Correspondingly, in the high-impedance state of the second display terminal 222, the second primary current path 321 is disconnected, as illustrated in FIG. 2.

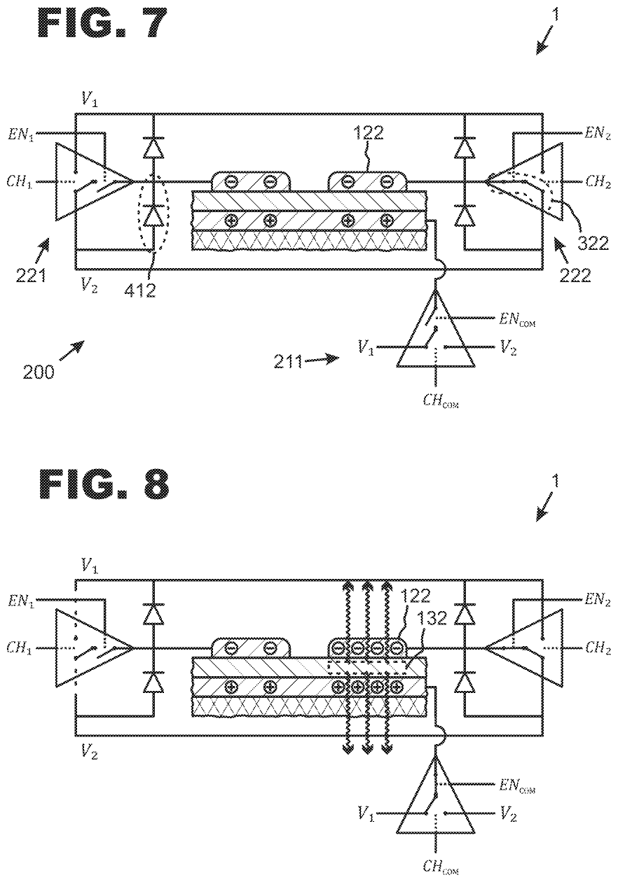

Additionally, each of the first display terminal 221 and the second display terminal 222 of the embodiment of FIGS. 1 to 8 has a second state. In its second state, the first display terminal 221 couples the first display electrode 121 to the secondary circuit node 202 via its first secondary current path 312, as illustrated in FIG. 6. Correspondingly, in its second state, the second display terminal 222 couples the second display electrode 122 to the secondary circuit node 202 via its second secondary current path 322, as illustrated in FIG. 7.

In the high-impedance state of the first display terminal 221, the first secondary current path 312 is disconnected. Correspondingly, in the high-impedance state of the second display terminal 222, the second secondary current path 322 is disconnected. In other embodiments, wherein a display terminal has a second state, wherein said display terminal couples its associated display electrode to a secondary circuit node via its secondary current path, said secondary current path may be disconnected in a high-impedance state of said display terminal.

The common display terminal 211 of the embodiment of FIGS. 1 to 8 a has a first state, as depicted in FIG. 1, and a high-impedance state, as depicted in FIG. 3. In the first state of the common display terminal 211, the common display electrode 111 is maintained at the second potential V₂.

In its first state, the common display terminal 211 may electrically couple the common display electrode 111 to the secondary circuit node 202. In other embodiments, a common display terminal may or may not electrically couple a common display electrode to a secondary circuit node in its first state.

The common display terminal 211 of the embodiment of FIGS. 1 to 8 also has a second state, as depicted in FIG. 6. In the second state of the common display terminal 211, the common display electrode 111 is maintained at the first potential V₁. In other embodiments, a common display terminal may or may not have such second state.

In its second state, the common display terminal 211 may electrically couple the common display electrode 111 to the primary circuit node 201. In other embodiments, a common display terminal may or may not electrically couple a common display electrode to a primary circuit node in its second state.

With reference to FIG. 1, the states of the first display terminal 221, the second display terminal 222, and the common display terminal 211 of the embodiment of FIGS. 1 to 8 are controlled by signaling. In other embodiments, any suitable method, for example, signaling, may be used to control the state(s) of one or more of a first display terminal, a second display electrode, and a common display terminal.

Each of the first display terminal 221, the second display terminal 222, and the common display terminal 211 is configured to receive an enable signal EN₁, EN₂, EN_{COM}, determining whether said terminal is to be maintained in its high-impedance state. If an enable signal corresponding to maintaining a high-impedance state (for example, logical 0) is received by one of the terminals, said terminal is maintained in its high-impedance state, irrespective of other signals received by said terminal. Nevertheless, if an enable signal corresponding to maintaining an enabled state (for example, logical 1) is received by one of the terminals, said terminal is set to some enabled state, for example, a first state or a second state, based on the contents of a channel signal CH₁, CH₂, CH_{COM} last received by said terminal.

As depicted in FIG. 1, the display driver unit 200 of the embodiment of FIGS. 1 to 8 has a rectifying first primary auxiliary current path 411 between the first display electrode 121 and the primary circuit node 201.

Herein, a “rectifying current path” may refer to a current path exhibiting asymmetric electrical conductance. A rectifying current path may generally exhibit a first electrical resistance for current passing along its primary conduction direction, i.e., its forward direction, and a second electrical resistance considerably higher than the first electrical resistance for current passing opposite its forward direction, i.e., along its reverse direction. A rectifying current path may be provided, for example, between the pins of a semiconductor diode.

In the embodiment of FIGS. 1 to 8, the first primary auxiliary current path 411 has a forward direction extending from the first display electrode 121 to the primary circuit node 201, since the first potential V₁ is higher than the second potential V₂. In other embodiments, a first primary auxiliary current path may have a forward direction extending in either direction between the first display electrode and a primary circuit node, depending on whether a first potential V₁ is higher or lower than a second potential V₂.

Additionally, the display driver unit 200 of the embodiment FIGS. 1 to 8 has a rectifying first secondary auxiliary current path 412 with a forward direction extending from the secondary circuit node 202 to the first display electrode 121, a rectifying second primary auxiliary current path 421 with a forward direction extending from the second display electrode 122 to the primary circuit node 201, and a rectifying second secondary auxiliary current path 422 with a forward direction extending from the second display electrode 122 and the secondary circuit node 202. In other embodiments, a display driver unit may or may not comprise one or more of a first secondary auxiliary current path, a second primary auxiliary current path, and a second secondary auxiliary current path. In said other embodiments, any auxiliary current path may have its forward direction extending in any suitable direction between a display electrode and a circuit node, depending on whether a first potential is higher or lower than a second potential.

FIGS. 1 to 8 depict a series of subsequent stages of a driving sequence of the display arrangement 1. The driving sequence comprises a first partial sequence, depicted in FIGS. 2 to 5, and a second partial sequence, depicted in FIGS. 6 to 8 and 1. In other embodiments, a driving sequence of a display arrangement may or may not comprise one or both of said partial sequences.

In embodiments, wherein a common display electrode of a first conductor layer of a display element of a display arrangement laterally overlaps each of a plurality of display electrodes of a second conductor layer of said display element at a separate overlapping region, a “partial sequence” of a driving sequence of said display arrangement may refer to a series of stages during which emission of light is brought about at least once, e.g., once, at each of said overlapping regions.

In general, a driving sequence of the display arrangement may comprise a series of stages similar or different to the stages of the driving sequence of the embodiment of FIGS. 1 to 8. In particular, any driving sequence of a display arrangement or partial sequence thereof may comprise any number of additional stages that are not disclosed herein with reference to any of FIGS. 1 to 8. For example, although only the first and the second partial sequence of the driving sequence of the display arrangement 1 are depicted in FIGS. 1 to 8, a driving sequence of a display arrangement may generally comprise any number of additional partial sequences not disclosed with reference to any of FIGS. 1 to 8.

With reference to FIG. 2, the display driver unit 200 of the embodiment of FIGS. 1 to 8 is configured to set the first display terminal 221 and the common display terminal 211 to their first states, while maintaining the second display terminal 222 in its high-impedance state.

Consequently, light is emitted by the first emissive part 131, as depicted by wavy arrows in FIG. 2. Light emitted by the first emissive part 131 passes through each of the first display electrode 121 and the common display electrode 111. As such, each of the first display electrode 121 and the common display electrode 111 is transparent. In other embodiments, at least one of a first display electrode and a common display electrode may be transparent.

Throughout this specification, an element or material being “transparent”, may refer to a quality, i.e., “transparency”, of said element or material of allowing light of wavelength(s) within a range of relevant wavelengths to propagate through such element or material. Said range of relevant wavelengths may generally depend on intended usage of such transparent element or material.

Additionally, in the embodiment of FIGS. 1 to 8, light emitted by the first emissive part 131 passes through the substrate 102. As such, the substrate 102 is transparent. In other embodiments, a substrate may or may not be transparent.

As depicted in FIG. 2, net charge of a first polarity accumulates at the first display electrode 121, when the first display terminal 221 and the common display terminal 211 are set to their first states. Additionally, net charge of a second polarity opposite to the first polarity accumulates at the common display electrode 111. In the embodiment of FIGS. 1 to 8, the first polarity is positive and the second polarity is negative, since the first potential V₁ is higher than the second potential V₂. In other embodiments, a first polarity may be positive or negative, depending on whether a first potential V₁ is higher or lower than a second potential V₂.

With reference to FIG. 3, the display driver unit 200 of the embodiment of FIGS. 1 to 8 is further configured to set the second display terminal 222 to its first state after setting the first display terminal 221 and the common display terminal 211 to their first states, as depicted in FIG. 2. The second display terminal 222 is set to its first state, while maintaining the first display terminal 221 and the common display terminal 211 in their high-impedance states, such that electrical current passes between the first display electrode 121 and the second display electrode 122 along the forward direction of the first primary auxiliary current path 411 and via the second display terminal 222.

Since the first primary auxiliary current path 411 and the second display terminal 222 of the embodiment of FIGS. 1 to 8 provide an uninterrupted current path from the first display electrode 121 to the second display electrode 122 and the first display terminal 221 is in its high-impedance state, current passes spontaneously from the first display electrode 121 to the second display electrode 122 until a voltage between the first display electrode 121 and the common display electrode 111 and a voltage between the second display electrode 122 and the common display electrode 111 become equal. In practice, this results in a partial net charge of the first polarity at the first display electrode 121 and at the second display electrode 122. Additionally, a net charge at the common display electrode 111 is also re-distributed within the common display electrode 111 in order to reach an equilibrium.

In other embodiments, a display driver unit may generally be configured to, after setting a first display terminal and a common display terminal to their first states, set a second display terminal to its first state, while maintaining said first display terminal and said common display terminal in their high-impedance states, such that electrical current passes between said first display electrode and said second display electrode along a forward direction of a first primary auxiliary current path and via a second display terminal. A display driver unit of a display arrangement being configured in such manner may generally reduce power consumption of said display driver unit and/or increase a brightness of a display element of said display arrangement.

With reference to FIG. 4, the display driver unit 200 of the embodiment of FIGS. 1 to 8 is configured to, after setting the second display terminal 222 to its first state, as depicted in FIG. 3, set the common display terminal 211 to its first state, while maintaining the first display terminal 221 in its high-impedance state and the second display terminal 222 in its first state. Consequently, light is emitted by the second emissive part 132, as depicted by wavy arrows in FIG. 4.

Light emitted by the second emissive part 132 passes through the second display electrode 122. As such, the second display electrode 122 is transparent. In other embodiments, at least one of a second display electrode and a common display electrode may be transparent.

As depicted in FIG. 4, additional net charge of the first polarity accumulates at the second display electrode 122, when the second display terminal 222 and the common display terminal 211 are set to their first states.

With reference to FIG. 5, the display driver unit 200 of the embodiment of FIGS. 1 to 8 is further configured to set the common display terminal 211 to its second state to at least partly discharge both the first display electrode 121 and the second display electrode 122. Generally, a display driver unit configured in such manner may enable increasing a fraction of activation time within a driving sequence of a display arrangement, which may, in turn, increase a brightness of a display element of said display arrangement. In other embodiments, a display driver unit may or may not be configured in such manner.

Generally, a display driver unit may be configured to set a common display terminal to its second state to at least partly discharge a first display electrode and a second display electrode, while maintaining a first display terminal in its first state or its high-impedance state and while maintaining a second display terminal in its first state or its high-impedance state.

Throughout this specification, “discharging” may refer to reduction or removal of net electrical charge from an electrode.

In the embodiment of FIGS. 1 to 8, the display driver unit 200 is configured set the common display terminal 211 to its second state to at least partly discharge the first display electrode 121 and the second display electrode 122, while maintaining the first display terminal 221 in its high-impedance state, as depicted in FIG. 5. In other embodiments, a display driver unit may or may not be configured to set a common display terminal to its second state to at least partly discharge each of a first display electrode and a second display electrode, while maintaining a first display terminal in its high-impedance state and/or while maintaining a second display terminal in its high-impedance state. Generally, a display driver unit being configured in such manner may enable having a lower number of display terminals enabled simultaneously, which may, in turn, enable usage of a wider variety of and/or less complicated display driver units in a display arrangement.

The discharging of both the first display electrode 121 and the second display electrode 122 concludes the first partial sequence of the driving sequence of the display arrangement 1, during which emission of light is achieved by coupling the second potential V₂ to the first conductor layer 110 and the first potential V₁ to the second conductor layer 120. In the following, stages included in the second partial sequence are described.

With reference to FIG. 6, the display driver unit 200 of the embodiment of FIGS. 1 to 8 is configured to, after (at least partly) discharging each of the first display electrode 121 and the second display electrode 122, as depicted in FIG. 5, set the first display terminal 221 and the common display terminal 211 to their second states, while maintaining the second display terminal 222 in its high-impedance state. Consequently, light is emitted by the first emissive part 131, as depicted by wavy arrows in FIG. 6. In other embodiments, a display driver unit may or may not be configured in such manner.

As depicted in FIG. 6, net charge of the second polarity accumulates at the first display electrode 121, when the first display terminal 221 and the common display terminal 211 are set to their second states. Additionally, net charge of the first polarity accumulates at the common display electrode 111.

With reference to FIG. 7, the display driver unit 200 of the embodiment of FIGS. 1 to 8 is further configured to, after setting the first display terminal 221 and the common display terminal 211 to their second states, as depicted in FIG. 6, set the second display terminal 222 to its second state, while maintaining the first display terminal 221 and the common display terminal 211 in their high-impedance states, such that electrical current passes between the first display electrode 121 and the second display electrode 122 along the forward direction of the first secondary auxiliary current path 412 and via the second display terminal 222. This results in a partial net charge of the second polarity at the first display electrode 121 and at the second display electrode 122. In other embodiments, a display driver unit may or may not be configured in such manner.

With reference to FIG. 8, the display driver unit 200 of the embodiment of FIGS. 1 to 8 is configured to, after setting the second display terminal 222 to its second state, as depicted in FIG. 7, set the common display terminal 211 to its second state, while maintaining the first display terminal 221 in its high-impedance state and the second display terminal 222 in its second state. Consequently, light is emitted by the second emissive part 132, as depicted by wavy arrows in FIG. 8. In other embodiments, a display driver unit may or may not be configured in such manner.

As depicted in FIG. 8, additional net charge of the second polarity accumulates at the second display electrode 122, when the second display terminal 222 and the common display terminal 211 are set to their second states.

Finally, referring back to FIG. 1, the display driver unit 200 of the embodiment of FIGS. 1 to 8 is configured to set the common display terminal 211 to its first state to discharge both the first display electrode 121 and the second display electrode 122. In other embodiments, a display driver unit may or may not be configured in such manner.

Such discharging of both the first display electrode 121 and the second display electrode 122 concludes the second partial sequence of the driving sequence of the display arrangement 1, during which emission of light is achieved by coupling the first potential V₁ to the first conductor layer 110 and the second potential V₂ to the second conductor layer 120.

Evidently, in the embodiment of FIGS. 1 to 8, the display driver unit 200 is configured to drive the display element 100 in a sequential manner in accordance with a driving sequence, comprising a first partial sequence, throughout which the second potential V₂ is applied to the common display electrode 111, when emission of light is brought about, and a second partial sequence, throughout which the first potential, V₁, is applied to the common display electrode 111, when emission of light is brought about. A display driver unit being configured to drive a display element in such manner may reduce a frequency at which a common display electrode must be discharged, which may, in turn, enable usage of a wider variety of and/or less complicated display driver units in a display arrangement. In other embodiments, a display driver unit may or may not be configured in such manner.

In the embodiment of FIGS. 1 to 8, a constant illumination order is used for both the first partial sequence and the second partial sequence, i.e., during both partial sequences, the first display terminal 221 is maintained at a state other than its high-impact state to bring about emission of light before the second display terminal 222 is maintained at a state other than its high-impact state to bring about emission of light. In other embodiments, any suitable illumination order(s), e.g., constant or varying illumination order, may be used for partial sequences of a driving sequence of a display arrangement.

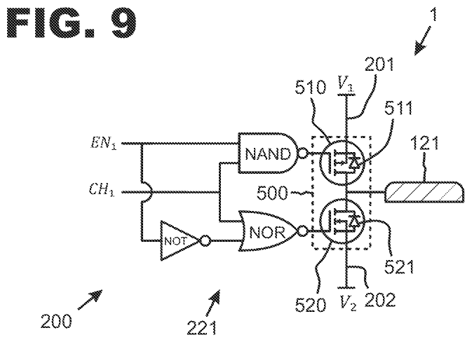

FIG. 9 depicts a schematic view of a first display terminal 221 of a display driver unit 200 of a display arrangement 1 according to an embodiment and its associated first display electrode 121. The embodiment of FIG. 9 may be in accordance with any of the embodiments disclosed with reference to, in conjunction with, and/or concomitantly with any of FIGS. 1 to 8. Additionally or alternatively, although not explicitly shown in FIG. 9, the embodiment of FIG. 9 or any part thereof may generally comprise any features and/or elements of the embodiment of FIGS. 1 to 8, which are omitted from FIG. 9.

Although a first display terminal 221 is depicted in FIG. 9, any display terminal(s), for example, one or more or a first display terminal, a second display terminal, and a common display terminal, of a display driver unit of a display arrangement may or may not comprise any features and/or elements of the embodiment of FIG. 9 disclosed herein.

The first display terminal 221 of the embodiment of FIG. 9 is implemented as a tri-state terminal with a high-impedance state. In other embodiments, any display terminal(s) of a display driver unit of a display arrangement, for example, a first display terminal, may or may not be implemented as such tri-state terminal.

In the embodiment of FIG. 9, the first display terminal 221 comprises a push-pull output stage 500. A display terminal, for example, a first display terminal, of a display driver unit of a display arrangement comprising a push-pull output stage may enable both amplifying emission activation signals and passing electrical current to and from a first display electrode as well as to and from a second display electrode to reduce power consumption of said display driver unit. In other embodiments, one or more of a first display terminal, a second display terminal, and a common display terminal of a display driver unit of a display arrangement may or may not comprise a push-pull output stage.

Herein, a “push-pull output stage” may refer to an electronic circuit, wherein a complementary pair of transistors is used to supply current to a load from a positive voltage source and to absorb current from a load to ground or a negative voltage supply.

The push-pull output stage 500 of the embodiment of FIG. 9 comprises a first transistor 510, and a second transistor 520. Each of the first transistor 510, and the second transistor 520 is a metal-oxide-semiconductor field-effect transistor (MOSFET). In other embodiments, wherein one or more of a first display terminal, a second display terminal, and a common display terminal of a display driver unit of a display arrangement comprises a push-pull output stage, said push-pull output stage may comprise a first transistor and a second transistor one or more, for example, each, of which may or may not be a MOSFET.

The first transistor 510 has its source connected to a primary circuit node 201, configured to be maintained at a first potential V₁, and its drain connected to the first display electrode 121. On the other hand, the second transistor 520 has its source connected to a secondary circuit node 202, configured to be maintained at a second potential V₂, and its drain connected to the first display electrode 121. In other embodiments, any suitable electrical connections may be utilized for a first transistor and a second transistor.

In the embodiment of FIG. 9, the first potential V₁ is higher than the second potential V₂. Consequently, the first transistor 510 has a p-type channel, and the second transistor 520 has an n-type channel. In other embodiments, a first potential V₁ may generally be higher or lower than a second potential V₂, and the types of first transistors and second transistor may be adjusted accordingly.

In the embodiment of FIG. 9, a first primary auxiliary current path extends through a first primary body diode structure 511 of the first transistor 510. Generally, an auxiliary current path extending through a body diode structure of a MOSFET may enable both amplifying emission activation signals and passing electrical current between a first display electrode and a second display electrode to reduce power consumption of said display driver unit. In other embodiments, one or more of a first primary auxiliary current path, a first secondary auxiliary current path, a second primary auxiliary current path, and a second secondary auxiliary current path may or may not extend through a body diode structure of a MOSFET. In said other embodiments, one or more of a first display terminal, a second display terminal, and a common display terminal of a display driver unit of a display arrangement may or may not comprise a push-pull output stage. In some embodiments, one or more of a first primary auxiliary current path, a first secondary auxiliary current path, a second primary auxiliary current path, and a second secondary auxiliary current path may extend through a body diode structure of a MOSFET of a push-pull output stage.

Herein, a “body diode structure” may refer to a semiconductor diode structure between a drain and a source of a MOSFET. Body diode structures may be commonly utilized in so-called power MOSFETs, i.e., MOSFETs designed to handle high power levels.

It is to be understood that the embodiments described above may be used in combination with each other. Several of the embodiments may be combined together to form a further embodiment.

It is obvious to a person skilled in the art that with the advancement of technology, the basic idea of the invention may be implemented in various ways. The invention and its embodiments are thus not limited to the examples described above, instead they may vary within the scope of the claims.

It will be understood that any benefits and advantages described above may relate to one embodiment or may relate to several embodiments. The embodiments are not limited to those that solve any or all of the stated problems or those that have any or all of the stated benefits and advantages.

The term “comprising” is used in this specification to mean including the feature(s) or act(s) followed thereafter, without excluding the presence of one or more additional features or acts. It will further be understood that reference to ‘an’ item refers to one or more of those items.

### REFERENCE SIGNS

V₁ first potential
V₂ second potential
V_{TH} activation voltage threshold
CH₁ first channel signal
CH₂ second channel signal
CH_{COM} common channel signal
EN₁ first enable signal
EN₂ second enable signal
EN_{COM} common enable signal

1 display arrangement
100 display element
101 base plane
102 substrate
110 first conductor layer
111 common display electrode
120 second conductor layer
121 first display electrode
122 second display electrode
130 emissive layer
131 first emissive part
132 second emissive part
133 phosphor layer
134 first insulating layer
135 second insulating layer
200 display driver unit
201 primary circuit node
202 secondary circuit node
211 common display terminal
221 first display terminal
222 second display terminal
311 first primary current path
312 first secondary current path
321 second primary current path
322 second secondary current path
411 first primary auxiliary current path
412 first secondary auxiliary current path
421 second primary auxiliary current path
422 second secondary auxiliary current path
500 push-pull output stage
510 first transistor
511 first primary body diode structure
520 second translator
1220 first secondary body diode structure

1. A display arrangement comprising a thin film display element with a layer structure extending substantially along a base plane defining a lateral extension of the thin film display element, the thin film display element comprising:
a first conductor layer comprising a common display electrode; and
a second conductor layer, comprising a first display electrode and a second display electrode, the common display electrode at least partly laterally overlapping each of the first display electrode and the second display electrode;
wherein the display arrangement comprises,
a display driver unit) with a primary circuit node configured to be maintained at a first potential, V₁,
a first display terminal associated with the first display electrode,
a second display terminal associated with the second display electrode, and
a common display terminal associated with the common display electrode;
wherein each of the first display terminal and the second display terminal has a first state,
wherein the first display terminal electrically couples the first display electrode to the primary circuit node via a first primary current path of the first display terminal, and a high-impedance state,
wherein the second display terminal electrically coupled the second display electrode to the primary circuit node a second primary current path of the second display terminal, and a high-impedance state,
wherein the first primary current path and the second primary current path is are disconnected the common display terminal has a first state,
wherein the common display electrode is maintained at a second potential, V₂, and a high-impedance state;
wherein the display driver unit has a rectifying first primary auxiliary current path between the first display electrode and the primary circuit node, and the display driver unit is configured to:
while maintaining the second display terminal in its high-impedance state, set the first display terminal and the common display terminal to their first states; and
after setting the first display terminal and the common display terminal to their first states, set the second display terminal to its first state, while maintaining the first display terminal and the common display terminal in their high-impedance states, such that electrical current passes between the first display electrode and the second display electrode along a forward direction of the rectifying first primary auxiliary current path and via the second display terminal.

2. The display arrangement according to claim 1, wherein the rectifying first primary auxiliary current path extends through a body diode structure of a metal-oxide-semiconductor field-effect transistor.

3. The display arrangement according to claim 1, wherein the common display terminal has a second state, wherein the common display electrode is maintained at the first potential, V₁, and the display driver unit is configured to:
after setting the second display terminal to its first state, set the common display terminal to its first state, while maintaining the first display terminal in its high-impedance state and the second display terminal in its first state.
after setting the common display terminal to its first state, set the common display terminal to its second state to at least partly discharge each of the first display electrode and the second display electrode.

4. The display arrangement according to claim 3, wherein the display driver unit is configured to set the common display terminal to its second state to at least partly discharge each of the first display electrode and the second display electrode, while maintaining the first display terminal in its high-impedance state and/or while maintaining the second display terminal in its high-impedance state.

5. The display arrangement according to claim 1, wherein the display driver unit is configured to drive the thin film display element in a sequential manner in accordance with a driving sequence, comprising a first partial sequence, throughout which the second potential, V₂, is applied to the common display electrode, when emission of light is brought about, and a second partial sequence, throughout which the first potential, V₁, is applied to the common display electrode, when emission of light is brought about.

6. The display arrangement according to claim 1, wherein at least one of the first display terminal and the second display terminal comprises a push-pull output stage.

7. The display arrangement according to claim 1, comprising:
an emissive layer between the first conductor layer and the second conductor layer), the emissive layer configured to emit light in consequence of voltage with a magnitude exceeding an activation voltage threshold, V_{TH}, coupled over the emissive layer; wherein a magnitude of a potential difference, |V₁−V₂|, between the first potential, V₁, and the second potential, V₂ exceeds the activation voltage threshold, V_{TH}.

8. The display arrangement according to claim 1, wherein the thin film display element is implemented as an inorganic thin film electroluminescent, TFEL, display element.
